(19) United States
(12) Patent Application Publication
(10) Pub. No.: US 2021/0112212 A1
(43) Pub. Date: Apr. 15, 2021

(54) IMAGING PIXELS HAVING PROGRAMMABLE DYNAMIC RANGE

(71) Applicant: SEMICONDUCTOR COMPONENTS INDUSTRIES, LLC, Phoenix, AZ (US)

(72) Inventor: Minseok OH, San Jose, CA (US)

(73) Assignee: SEMICONDUCTOR COMPONENTS INDUSTRIES, LLC, Phoenix, AZ (US)

(21) Appl. No.: 16/676,063

(22) Filed: Nov. 6, 2019

Related U.S. Application Data
(60) Provisional application No. 62/913,245, filed on Oct. 10, 2019.

(51) Int. Cl. H04N 5/355; H04N 5/3745; H01L 27/146

(52) U.S. Cl. CPC H04N 5/3559; H01L 27/14612; H04N 5/37452

(57) ABSTRACT

An image sensor may include one or more pixels having a charge overflow structure for increased dynamic range. A charge overflow structure adjacent to the photodiode may form a potential barrier. When the amount of charge in the photodiode exceeds the potential barrier, the charge may overflow from the photodiode. The overflow charge may be disposed of when a transistor is asserted and funnels the charge to a power supply voltage. The overflow charge may be stored in a storage capacitor when the transistor is deasserted. Control circuitry may cycle the transistor between an asserted state and a deasserted state during the integration time of the imaging pixel. The known percentage of time that the overflow charge is disposed of may be used to extrapolate how much overflow charge was generated, thus increasing the dynamic range of the pixel.

### CROSS-REFERENCE TO RELATED APPLICATIONS

This application claims the benefit of U.S. Provisional Patent Application No. 62/913,245, filed on Oct. 10, 2019, the entire contents of which is incorporated herein by reference.

### BACKGROUND

This relates generally to imaging devices, and more particularly, to imaging devices having high dynamic range imaging pixels.

Image sensors are commonly used in electronic devices such as cellular telephones, cameras, and computers to capture images. In a typical arrangement, an image sensor includes an array of image pixels arranged in pixel rows and pixel columns. Circuitry may be coupled to each pixel column for reading out image signals from the image pixels.

Typical image pixels contain a photodiode for generating charge in response to incident light. Image sensors can operate using a global shutter or a rolling shutter scheme. In a global shutter, every pixel in the image sensor may simultaneously capture an image, whereas in a rolling shutter each row of pixels may sequentially capture an image.

Some conventional image sensors may be able to operate in a high dynamic range (HDR) mode. HDR operation may be accomplished in image sensors by assigning alternate rows of pixels different integration times. However, conventional image sensors may sometimes experience lower than desired resolution, lower than desired sensitivity, higher than desired noise levels, and lower than desired quantum efficiency.

It would therefore be desirable to be able to provide improved high dynamic range operation in image sensors.

### BRIEF DESCRIPTION OF THE DRAWINGS

FIG. 1 is a diagram of an illustrative system that includes an imaging system and a host subsystem in accordance with an embodiment.

FIG. 2 is a diagram of an illustrative image sensor having an array of image pixels and control circuitry coupled to the array of image pixels in accordance with an embodiment.

FIG. 3 is a circuit diagram of an illustrative imaging pixel with high dynamic range in accordance with an embodiment.

FIG. 4 is a timing diagram showing an illustrative method of operating the imaging pixel of FIG. 3 in accordance with an embodiment.

FIG. 5 is a top view of the imaging pixel of FIG. 3 showing an illustrative layout for the imaging pixel in accordance with an embodiment.

FIGS. 6 and 7 are cross-sectional side views of the imaging pixel of FIG. 5 in accordance with an embodiment.

FIGS. 8A and 8B are potential diagrams showing the potential at various positions within the imaging pixel in accordance with an embodiment.

FIG. 9 is a top view of the imaging pixel of FIG. 3 showing an illustrative layout for the imaging pixel with only one overflow transistor gate in accordance with an embodiment.

### DETAILED DESCRIPTION

Embodiments of the present invention relate to image sensors, and more particularly, to image sensors having pixels that each contain overflow structures for high dynamic range imaging. It will be recognized by one skilled in the art, that the present exemplary embodiments may be practiced without some or all of these specific details. In other instances, well-known operations have not been described in detail in order not to unnecessarily obscure the present embodiments.

Imaging systems having digital camera modules are widely used in electronic devices such as digital cameras, computers, cellular telephones, and other electronic devices. A digital camera module may include one or more image sensors that gather incoming light to capture an image.

In some situations, imaging systems may form a portion of a larger system such as a surveillance system or a safety system for a vehicle (e.g., an automobile, a bus, or any other vehicle). In a vehicle safety system, images captured by the imaging system may be used by the vehicle safety system to determine environmental conditions surrounding the vehicle. As examples, vehicle safety systems may include systems such as a parking assistance system, an automatic or semi-automatic cruise control system, an auto-braking system, a collision avoidance system, a lane keeping system (sometimes referred to as a lane drift avoidance system), etc.

In at least some instances, an imaging system may form part of a semi-autonomous or autonomous self-driving vehicle. Such imaging systems may capture images and detect nearby vehicles using those images. If a nearby vehicle is detected in an image, the vehicle safety system may sometimes operate a warning light, a warning alarm, or may activate braking, active steering, or other active collision avoidance measures. A vehicle safety system may use continuously captured images from an imaging system having a digital camera module to help avoid collisions with objects (e.g., other automobiles or other environmental objects), to help avoid unintended drifting (e.g., crossing lane markers) or to otherwise assist in the safe operation of a vehicle during any normal operation mode of the vehicle.

Image sensors may include arrays of image pixels. The pixels in the image sensors may include photosensitive elements such as photodiodes that convert the incoming light into electric charge. Image sensors may have any number of pixels (e.g., hundreds or thousands or more). A typical image sensor may, for example, have hundreds, thousands, or millions of pixels (e.g., megapixels).

In some conditions, such as high light conditions, more charge may accumulate in a photodiode of an image sensor pixel than can be stored within the pixel. For instance, storage nodes or photodiodes in a pixel may only be capable of storing a limited amount of charge. This limited charge storage capacity may reduce the dynamic range of the pixel, which is undesirable. In order to overcome this dynamic range limitation, it may be desirable to include a mechanism within a pixel for directing charge over a certain threshold to either an additional storage node in the pixel or to a pixel voltage supply.

Overflow charges that are routed to the pixel voltage supply may be disposed of. Such disposal of charges may be performed in a manner such that the amount of charge disposed is known, which may be accounted for by downstream processing circuitry. Overflow charges that are routed to the storage node(s) may be read out separately from non-overflow charges. The magnitude of the overflow charge signal that is read out may be a known fraction of the total overflow charge. Thus, a portion of the charge accumulated in the photodiode may be kept track of by the image sensor without the need for storing said charge, thereby increasing the dynamic range of the pixel.

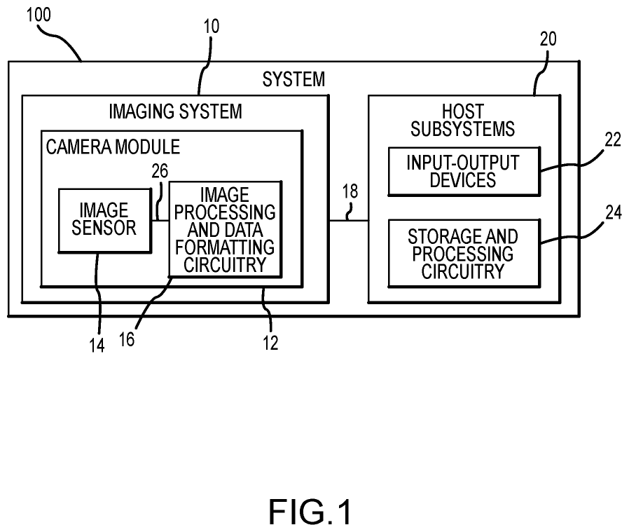

FIG. 1 is a diagram of an illustrative imaging and response system including an imaging system that uses an image sensor to capture images. System 100 of FIG. 1 may be a vehicle safety system (e.g., an active braking system or other vehicle safety system), may be a surveillance system, or may be an electronic device such as a camera, a cellular telephone, a video camera, or other electronic device that captures digital image data.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses. The lenses in camera module 12 may, as an example, include M*N individual lenses arranged in an M×N array. Individual image sensors 14 may be arranged in a corresponding M×N image sensor array (as an example). The values of M and N may each be equal to or greater than one, may each be equal to or greater than two, may exceed 10, or may have any other suitable values. Each image sensor in camera module 12 may be identical or there may be different types of image sensors in a given image sensor array integrated circuit.

During image capture operations, each lens may focus light onto an associated image sensor 14. Image sensor 14 may include photosensitive elements (i.e., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16 via path 26. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Host subsystem 20 may include an active control system that delivers control signals for controlling vehicle functions such as braking or steering to external devices. Host subsystem 20 may include processing software for detecting objects in images, detecting motion of objects between image frames, determining distances to objects in images, filtering or otherwise processing images provided by imaging system 10. Host subsystem 20 may include a warning system configured to disable imaging system 10 and/or generate a warning (e.g., a warning light on an automobile dashboard, an audible warning, or other warning) in the event that verification data associated with an image sensor indicates that the image sensor is not functioning properly.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, etc. During operation of imaging system 10, camera module 12 may continuously capture and provide image frames to host subsystem 20.

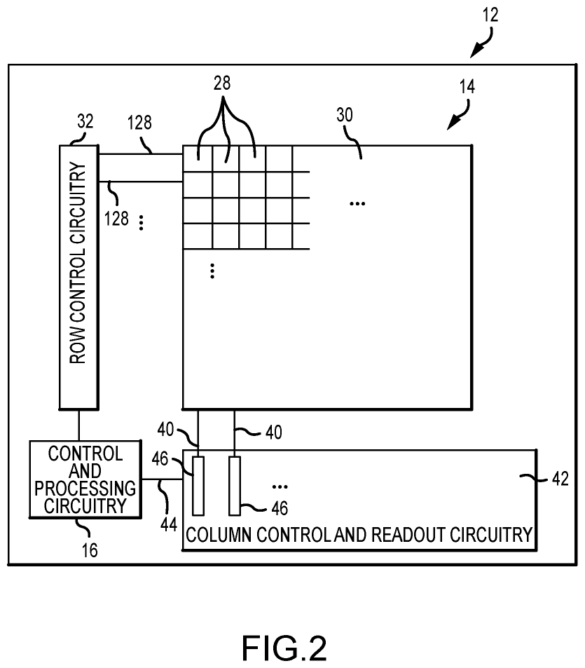

An example of an arrangement for camera module 12 is shown in FIG. 2. As shown in FIG. 2, camera module 12 includes image sensor 14 and control and processing circuitry 16. Image sensor 14 may include a pixel array such as array 30 of pixels 28 (sometimes referred to herein as image sensor pixels or image pixels 28). Control circuitry 16 may be coupled to row control circuitry 32 and may be coupled to column control and readout circuitry 42 via global data path 44. Row control circuitry 32 may receive row addresses from control circuitry 16 and may supply corresponding row control signals to image pixels 28 over control paths 128 (e.g., dual conversion gain control signals, pixel reset control signals, charge transfer control signals, blooming control signals, row select control signals, or any other desired pixel control signals). Column control and readout circuitry 42 may be coupled to the columns of pixel array 30 via one or more conductive lines such as column lines 40. Column lines 40 may be coupled to each column of image pixels 28 in image pixel array 30 (e.g., each column of pixels may be coupled to a corresponding column line 40). Column lines 40 may be used for reading out image signals from image pixels 28 and for supplying bias signals (e.g., bias currents or bias voltages) to image pixels 28. During image pixel readout operations, a pixel row in image pixel array 30 may be selected using row control circuitry 32 and image data associated with image pixels 28 of that pixel row may be read out by circuitry 42 on column lines 40.

Column control and readout circuitry 42 may include a number of column readout circuits 46. Each column readout circuit 46 may be coupled to a corresponding column line 40 and may read out and receive image signals from pixels 28 coupled to the corresponding column line. Each column readout circuit 46 may include column circuitry such as a column amplifier for amplifying signals read out from array 20, sample and hold circuitry for sampling and storing signals read out from array 20, analog-to-digital converter (ADC) circuit for converting read out analog signals to corresponding digital signals, and column memory for storing the read out signals and any other desired data. Column readout circuits 46 may output digital pixel values to control and processing circuitry 16 over line 44.

Array 30 may have any number of rows and columns. In general, the size of array 30 and the number of rows and columns in array 30 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

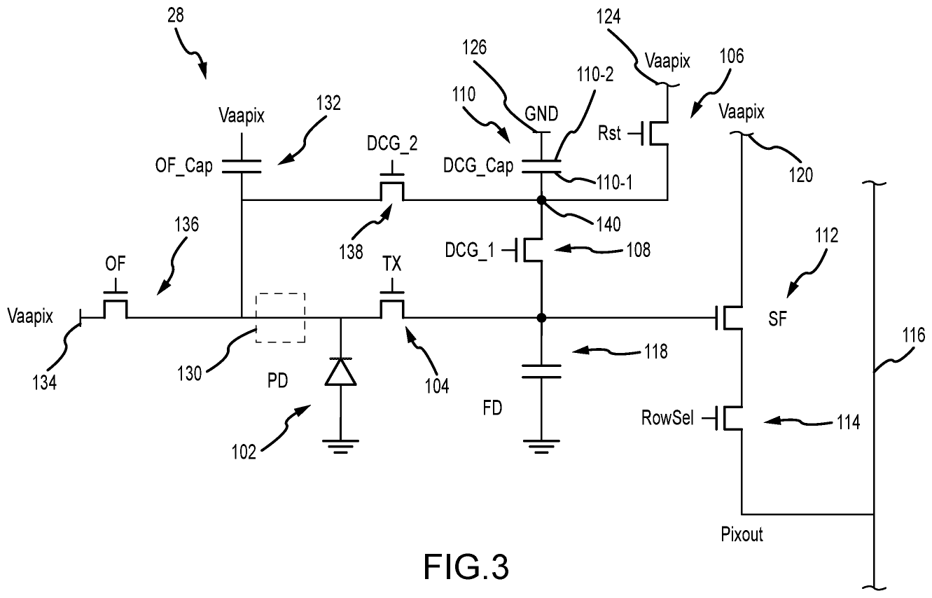

FIG. 3 is a circuit diagram of an imaging pixel having a high dynamic range. As shown in FIG. 3, image pixel 28 includes photosensitive element 102 (e.g., a photodiode). Photosensitive element 102 has a first terminal that is coupled to ground. The second terminal of photosensitive element 102 is coupled to a node between transfer transistor 104 and potential barrier 130. Photodiode 102 may generate charge in response to incident light. Photodiode 102 may be a doped semiconductor region (e.g., a region in a silicon substrate that is doped by ion implantation, impurity diffusion, or other doping process). The photodiode may generate charge proportional to the amount of light received at the photodiode. The generated charge may accumulate in the photodiode.

Potential barrier 130 may allow charge exceeding a certain amount to overflow from photodiode 102. Potential barrier 130 may sometimes be referred to as charge overflow barrier 130, charge overflow structure 130, etc. If the amount of charge accumulated in the photodiode is less than the charge overflow threshold, all of the charge may remain in the photodiode. If the amount of charge accumulated in the photodiode exceeds the charge overflow threshold, the charge exceeding the threshold may overflow potential barrier 130 and either be stored in overflow charge storage capacitor 132 (OF_Cap) or disposed of at bias voltage supply terminal 134.

Potential barrier 130 may be formed by a doped semiconductor region (e.g., a region in a silicon substrate that is doped by ion implantation, impurity diffusion, or other doping process). In some cases, the potential barrier 130 may be a diode. In this case, the charge overflow barrier 130 and the photodiode 102 may be referred to as diodes in series. This example is merely illustrative. In other arrangements, potential barrier 130 may be formed by a transistor having a gate that is biased to an intermediate level to control the charge overflow threshold.

Transistor 136 and overflow charge storage capacitor 132 may both be coupled to potential barrier 130. Transistor 136 (sometimes referred to as overflow control transistor 136, overflow transistor 136, etc.) may be interposed between potential barrier 130 and bias voltage supply terminal 134. Bias voltage supply terminal 134 may provide a bias voltage (V_{AAPIX}). When transistor 136 is asserted, charge that overflows potential barrier 130 will be disposed of at bias voltage supply terminal 134. When transistor 136 is not asserted, charge that overflows potential barrier 130 will be stored at overflow charge storage capacitor 132 (sometimes referred to as capacitor 132, storage capacitor 132, overflow capacitor 132, charge storage region 132, etc.). Charge storage region 132 may be formed from other charge storing components if desired (e.g., a storage diode, storage gate, etc.).

Transfer transistor 104 is coupled to floating diffusion (FD) region 118. Floating diffusion region 118 may be a doped semiconductor region (e.g., a region in a silicon substrate that is doped by ion implantation, impurity diffusion, or other doping process). Floating diffusion 118 has an associated capacitance. Gain select transistor 108 has a first terminal coupled to floating diffusion region 118 and a second terminal coupled to capacitor 110 (DCG_Cap). Dual conversion gain capacitor 110 (sometimes referred to as storage capacitor 110) may have a first plate 110-1 (sometimes referred to as an upper plate or top plate) coupled to the second terminal of the gain select transistor. Dual conversion gain capacitor 110 may have a second plate 110-2 (sometimes referred to as a lower plate or bottom plate) that is coupled to voltage supply 126. Voltage supply may provide a voltage GND.

A reset transistor 106 may be coupled between floating diffusion region 118 and voltage supply 124 through gain select transistor 108. Voltage supply 124 may provide a voltage V_{AAPIX}. When transistors 108 and 106 are simultaneously asserted, the floating diffusion region 118 will be reset to a reset voltage.

Transistor 138 may be coupled between overflow capacitor 132 and a node 140 that is interposed between storage capacitor 110 and gain select transistor 108. Transistors 138 and 108 may be asserted simultaneously to transfer charge from overflow capacitor 132 to floating diffusion region 118.

In this application, each transistor is illustrated as having three terminals: a source, a drain, and a gate. The source and drain terminals of each transistor may be changed depending on how the transistors are biased and the type of transistor used. For the sake of simplicity, the source and drain terminals are referred to herein as source-drain terminals or simply terminals.

Source follower transistor 112 (SF) has a gate terminal coupled to floating diffusion region 118. Source follower transistor 112 also has a first source-drain terminal coupled to voltage supply 120. Voltage supply 120 may provide a bias voltage V_{AAPIX}. The power supply voltage at bias voltage supply terminals 120, 124, 126, and 134 may be the same or may be different. A second source-drain terminal of source follower transistor 112 is coupled to column output line 116 through row select transistor 114. The source follower transistor, row select transistor, and column output line may sometimes collectively be referred to as a readout circuit or as readout circuitry.

A gate terminal of transfer transistor 104 receives control signal TX. A gate terminal of gain select transistor 108 receives control signal DCG_1. A gate terminal of reset transistor 106 receives control signal RST. A gate terminal of row select transistor 114 receives control signal RowSel. A gate terminal of transistor 138 receives control signal DCG_2. A gate terminal of overflow control transistor 136 receives control signal OF. Control signals TX, DCG_1, RST, RowSel, OF, and DCG_2 may be provided by row control circuitry (e.g., row control circuitry 32 in FIG. 2) over control paths (e.g., control paths 128 in FIG. 2).

Gain select transistor 108 and dual conversion gain capacitor 110 may be used by pixel 34 to implement a dual conversion gain mode. In particular, pixel 34 may be operable in a high conversion gain mode and in a low conversion gain mode. If gain select transistor 108 is deasserted, pixel 34 will be placed in a high conversion gain mode. If gain select transistor 108 is asserted, pixel 34 will be placed in a low conversion gain mode. When gain select transistor 108 is turned on (asserted), the dual conversion gain capacitor 110 may be switched into use to provide floating diffusion region 118 with additional capacitance. This results in lower conversion gain for pixel 34. When gain select transistor 108 is turned off (deasserted), the additional loading of the capacitor is removed and the pixel reverts to a relatively higher pixel conversion gain configuration.

During the integration period, transistor 136 may be selectively asserted to direct the charge that overflows potential barrier 130 on one of two paths (e.g., to be disposed of at voltage supply 134 or stored at capacitor 132). This arrangement allows the dynamic range of the pixel to be easily controlled by adjusting the amount of time transistor 136 is asserted. Consider an example in which transistor 136 is asserted for 75% of the integration time. For the remaining 25% of the cycle, transistor 136 is deasserted. This means that, of the overflow charge that passes potential barrier 130, 75% is drained to voltage supply 134 and only 25% is transferred to storage capacitor 132. This known ratio may be used to extrapolate a detected overflow signal. In this case, for example, the amount of charge sampled from capacitor 132 may be multiplied by four (because integration was only occurring 25% of the time) to determine how much overflow charge was actually present. This effectively increases the storage capacity of storage capacitor 132 by four times, which improves the dynamic range of the pixel.

If desired, pixel 28 may be split between multiple semiconductor substrates. One or more conductive interconnect layers may be used to electrically connect the components on the different semiconductor substrates. The pixel may be split between semiconductor substrates at any desired points within the circuit.

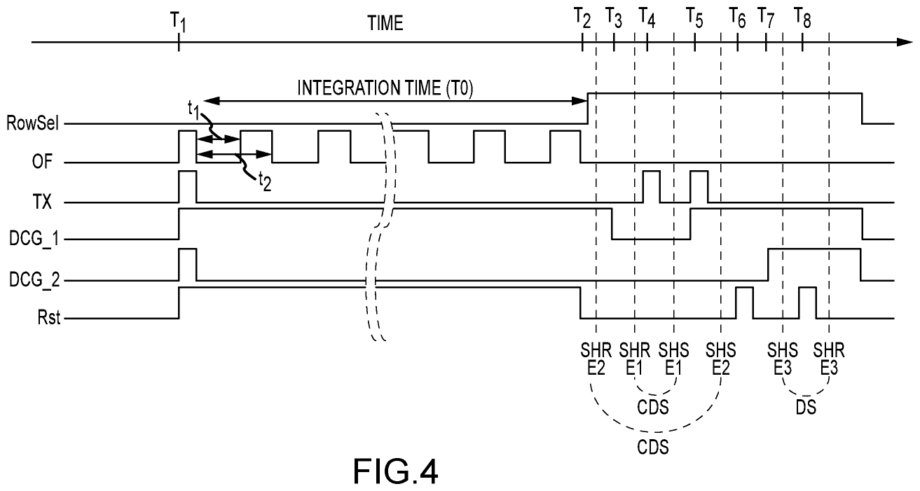

FIG. 4 is a timing diagram showing operation of the pixel of FIG. 3. First, a reset operation may be performed to reset the photodiode, floating diffusion region, and capacitors. As shown, at T₁, control signals OF, TX, DCG_1, DCG_2, and RST may be raised high, thus asserting transistors 136, 104, 108, 138, and 106 of pixel 28. Because transistors 104, 108, and 106 are all asserted, photodiode 102 is coupled to bias voltage supply terminal 124 and is therefore reset. Because transistors 108 and 106 are asserted, floating diffusion region 118 is coupled to bias voltage supply terminal 124 and is therefore reset. Because transistor 106 is asserted, capacitor 110 is coupled to bias voltage supply terminal 124 and is therefore reset. Transistors 106 and 138 are asserted, coupling capacitor 132 to bias voltage supply terminal 124. Transistor 136 is also asserted, coupling capacitor 132 to bias voltage supply terminal 134.

Once the photodiode, floating diffusion region, and capacitors are reset, control signals TX and DCG_2 may be lowered and an integration time (T0) may begin. During the integration time, charge accumulates in photodiode 102. Charge exceeding a certain amount (set by charge overflow barrier 130) will overflow the photodiode. When control signal OF is high and transistor 136 is asserted, the overflow charge will be disposed of at supply terminal 134. When control signal OF is low and transistor 136 is deasserted, the overflow charge will be stored at capacitor 132. As shown in FIG. 4, control signal OF may be toggled between high and low states throughout the integration time. The OF control signal may cycle between high and low states at a consistent rate. The amount of time the OF signal is high in each cycle sets the dynamic range of the pixel.

As shown in FIG. 4, the OF signal is low for a first time period t₁ in each cycle, with each cycle having an overall length t₂. The cycle is then repeated throughout the integration time. In FIG. 4, the OF signal is therefore low for a given percentage of each cycle defined by t₁/t₂. The frequency of asserting control signal OF may be controlled in a pseudo random nature in order to mitigate LED frequency gaps which could be present with a constant frequency. For example, if the control signal OF is configured to be asserted for 50% of the integration time, the OF control signal may be asserted with a constant frequency (e.g., 1 millisecond asserted, then 1 millisecond deasserted, then 1 millisecond asserted, then 1 millisecond deasserted, etc.). Alternatively, the duration of each assertion and deassertion may vary across the integration time while still totaling 50% of the integration time.

The percentage of the integration time that the control signal OF is asserted may be referred to as the duty cycle. The duty cycle may be predetermined or may be updated dynamically by control circuitry in the image sensor (e.g., in response to incident light levels). For example, control signal OF may be asserted more than 95% of the time, more than 90% of the time, more than 80% of the time, more than 70% of the time, more than 60% of the time, more than 50% of the time, more than 40% of the time, more than 30% of the time, more than 20% of the time, more than 10% of the time, more than 5% of the time, less than 95% of the time, less than 90% of the time, less than 80% of the time, less than 70% of the time, less than 60% of the time, less than 50% of the time, less than 40% of the time, less than 30% of the time, less than 20% of the time, less than 10% of the time, less than 5% of the time, between 60% and 90% of the time, between 10% and 40% of the time, etc. This is also true for the control signal OF being deasserted. The control signal OF may be deasserted more than 95% of the time, more than 90% of the time, more than 80% of the time, more than 70% of the time, more than 60% of the time, more than 50% of the time, more than 40% of the time, more than 30% of the time, more than 20% of the time, more than 10% of the time, more than 5% of the time, less than 95% of the time, less than 90% of the time, less than 80% of the time, less than 70% of the time, less than 60% of the time, less than 50% of the time, less than 40% of the time, less than 30% of the time, less than 20% of the time, less than 10% of the time, less than 5% of the time, between 60% and 90% of the time, between 10% and 40% of the time, etc.

Said another way, the time that control signal OF is high (and transistor 136 is asserted) divided by the time that control signal OF is low (and transistor 136 is deasserted) may be equal to 1, greater than 1, greater than 2, greater than 3, greater than 4, greater than 10, greater than 20, less than 20, less than 10, less than 0.5, less than 0.1, less than 0.05, more than 0.05, etc. Additionally the control signal OF can remain off for the duration of the integration time (for a ratio of 0 where all charge flows to overflow capacitor 132).

The dynamic range of the pixel may therefore be easily controlled by selecting the amount of time OF is asserted. The more time OF is asserted, the higher the dynamic range of the pixel will be. However, the more time OF is asserted, the worse the signal to noise ratio (SNR) of the sample will be. Therefore, the duty cycle of OF may be dynamically updated based on incident light levels sensed in the scene. For example, when incident light levels are high, the OF control signal may be asserted for a higher percentage of time to increase dynamic range. Alternatively, for example, when incident light levels are low, the OF control signal may be asserted for a lower percentage of time to increase signal-to-noise ratio (SNR).

After the integration time ends, readout operations may be performed at T₂. The readout operations described herein may include double sampling (DS) readout operations. In double sampling, a reset value and a signal value are obtained during readout. The reset value may then be subtracted from the signal value during subsequent processing to help correct for noise. The double sampling may be correlated double sampling (in which the reset value is sampled before the signal value and both the signal value and the reset value have the same charge injection, often referred to as KTC noise or KTC offset) or uncorrelated double sampling (in which the reset value is sampled after the signal value is sampled and the KTC noise is not the same between both the signal value and the reset value). Sampling the reset level for a double sampling readout may be referred to as sample-and-hold reset (SHR) whereas sampling the signal level for a double sampling readout may be referred to as sample-and-hold signal (SHS).

In FIG. 4, three different double sampling readouts are performed. The row select control signal RowSel may be set high during readout operations. Next, the reset level of the floating diffusion region may be sampled as shown by SHR E2. SHR E2 may occur while DCG_1 is high. This means that transistor 108 is asserted and the pixel is in a low conversion gain mode. SHR E2 may therefore sometimes be referred to as a low conversion gain reset sampling. At T₃, DCG_1 is lowered, deasserting transistor 108 and placing the pixel in a relatively high conversion gain mode. The reset level of the floating diffusion region is sampled again at SHR E1. SHR E1 may therefore sometimes be referred to as a high conversion gain reset sampling.

At T₄, transfer transistor 104 is asserted, transferring charge from photodiode 102 to floating diffusion region 118. The signal level of the floating diffusion is then sampled at SHS E1. SHS E1 occurs while the pixel is in the high conversion gain mode, so SHS E1 may sometimes be referred to as a high conversion gain signal sampling. At T₅, transfer transistor 104 and gain select transistor 108 are asserted to transfer any remaining charge from PD 102 which exceeded the capacity of FD 118 in the high conversion gain mode. The signal level of the floating diffusion is then sampled at SHS E2. SHS E2 occurs while the pixel is in the low conversion gain mode, so SHS E2 may sometimes be referred to as a low conversion gain signal sampling.

At T₆, the RST control signal may be raised and transistor 106 is therefore asserted. This causes the floating diffusion region to be reset to a reset voltage. Next, DCG_2 is raised at T₇, asserting transistor 138. Because both transistors 138 and 108 are asserted, charge will be shared between overflow capacitor 132, dual conversion gain capacitor 110, the floating diffusion region 118, and the channel capacitance of transistors 138 and 108. Next, the signal level of the floating diffusion region may be sampled as shown by SHS E3. SHS E3 may occur while DCG_1 is high. This means that transistor 108 is asserted and the pixel is in a low conversion gain mode. SHS E3 may therefore sometimes be referred to as a low conversion gain signal sampling. After SHS E3, the reset transistor 106 is again asserted at T₅ to reset the floating diffusion region. The reset level of the floating diffusion region may be sampled as shown by SHR E3. SHR E3 may occur while DCG_1 is high. This means that transistor 108 is asserted and the pixel is in a low conversion gain mode. SHR E3 may therefore sometimes be referred to as a low conversion gain reset sampling.

SHR E1 may be subtracted from SHS E1 to obtain an ‘E1’ correlated double sampling value. SHR E2 may be subtracted from SHS E2 to obtain an ‘E2’ correlated double sampling value. SHR E3 may be subtracted from SHS E3 to obtain an ‘E3’ uncorrelated double sampling value. The E1 CDS result may be a high conversion gain sampling of the charge in the photodiode. The E2 CDS result may be a low conversion gain sampling of the charge in the photodiode. The E3 DS result may be a low conversion gain sampling of the charge in the overflow capacitor 132.

The example of a method of operating pixel 28 in FIG. 3 shown in FIG. 4 is merely illustrative. In general, any desired readout operations may be performed.

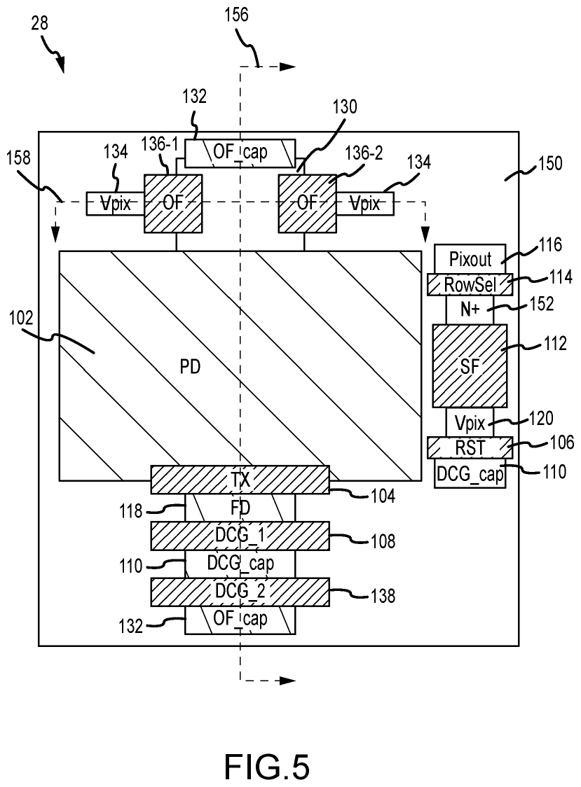

FIG. 5 is a top view showing an illustrative layout for the high dynamic range imaging pixel of FIG. 3. As shown in FIG. 5, pixel 28 may include a photodiode 102 formed in substrate 150. Substrate 150 may be a semiconductor substrate (e.g., silicon or another desired material). Herein, an example will be described where the substrate is a p-type semiconductor substrate and photodiode 102 is formed from an n-type doped portion of the substrate. However, it should be understood that the dopant types of all components described herein may be reversed if desired.

Transfer transistor 104 (e.g., a conductive gate for the transistor) is formed between photodiode 102 and floating diffusion region 118. Gain select transistor 108 (e.g., a conductive gate for the transistor) is formed between floating diffusion region 118 and dual conversion gain capacitor 110. Transistor 138 (e.g., a conductive gate for the transistor) is formed between dual conversion gain capacitor 110 and overflow capacitor 132. As shown in FIG. 5, transistors 104, 108, and 138 are formed on a first side of the photodiode.

Potential barrier 130 may be formed on a second side of the photodiode opposite transistors 104, 108, and 138. Potential barrier 130 may be formed from an n-type doped portion of substrate 150. Potential barrier 130 is interposed between photodiode 102 and overflow capacitor 132. Overflow transistors 136 (e.g., a conductive gate for the transistors) are formed on first and second opposing sides of the potential barrier. The same control signal OF may be applied to gates 136-1 and 136-2. When transistors 136-1 and 136-2 are asserted, charge that overflows potential barrier 130 will be drained to voltage supply 134. When transistors 136-1 and 136-2 are not asserted, charge that overflows potential barrier 130 will be transferred to overflow capacitor 132. In FIG. 5, transistor 136 (from FIG. 3) is depicted as having two conductive gates 136-1 and 136-2. This type of arrangement may be described as a single transistor having two conductive gates (e.g., a split gate) or as two transistors each having a respective conductive gate.

FIG. 5 also shows how source follower transistor 112 (e.g., a conductive gate for the transistor), row select transistor 114 (e.g., a conductive gate for the transistor), and reset transistor 106 (e.g., a conductive gate for the transistor) may be formed on a third side of the photodiode. An n-type doped region 152 may be formed between source follower transistor 112 and row select transistor 114. Row select transistor 114 may be formed between n-type doped region 152 and a pixel output portion 116 (e.g., an n-type doped region connected to column output line 116). Source follower transistor 112 is coupled between n-type doped region 152 and bias voltage supply terminal 120. The reset transistor 106 is interposed between bias voltage supply terminal 120 and dual conversion gain capacitor 110.

Conductive interconnects (sometimes referred to as conductive paths) may electrically connect the gate of source follower transistor 112 to floating diffusion region 118, may electrically connect the two depicted portions of overflow capacitor 132 on opposing sides of the photodiode, and may electrically connect the two depicted portions of dual conversion gain capacitor 110.

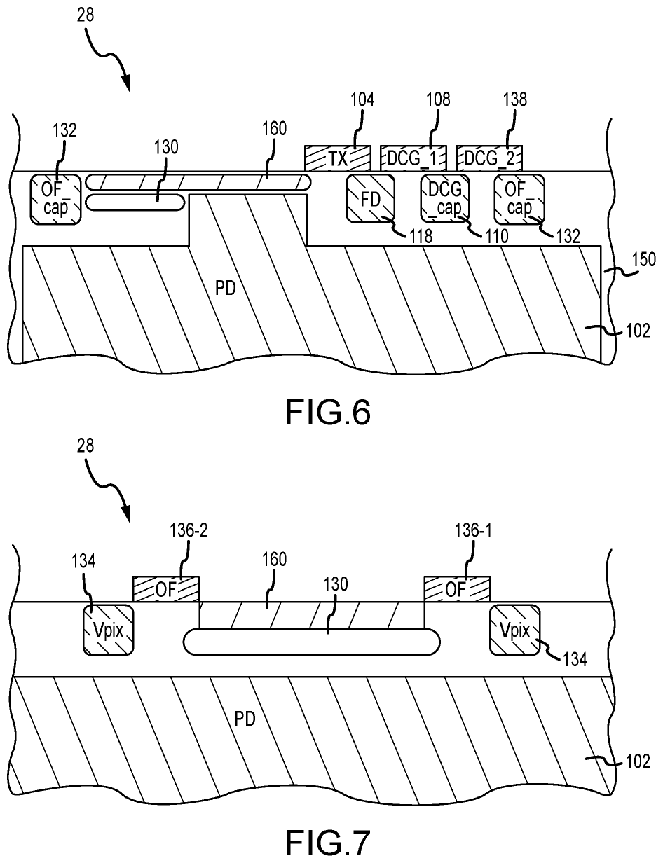

FIG. 6 is a cross-sectional side view taken along line 156 in FIG. 5. As shown in FIG. 6, photodiode 102 may have a portion that extends towards the upper surface of substrate 150. A p-type pinning layer may be formed over this portion of the photodiode between the photodiode and the upper surface (sometimes referred to as the backside) of the substrate. The p-type pinning layer may suppress dark current within the pixel.

Pinning layer 160 may be shared between photodiode 102 and potential barrier 130. In other words, a continuous pinning layer is formed both over the extension portion of photodiode 102 and adjacent potential barrier 130. Potential barrier 130 is interposed between photodiode 102 and overflow capacitor 132. When overflow gates 136-1 and 136-2 are not asserted, potential barrier 130 may direct overflow charge to overflow capacitor 132. FIG. 6 also shows the gates for transfer transistor 104, gain select transistor 108, and transistor 138 formed on the surface of substrate 150.

FIG. 7 is a cross-sectional side view taken along line 158 in FIG. 5. As shown in FIG. 7, gates 136-1 and 136-2 may be formed on first and second opposing sides of potential barrier 130 (and corresponding pinning layer 160). When the control signal OF applied to gates 136-1 and 136-2 is raised high, charge that overflows potential barrier 130 may be funneled to the voltage supply 134.

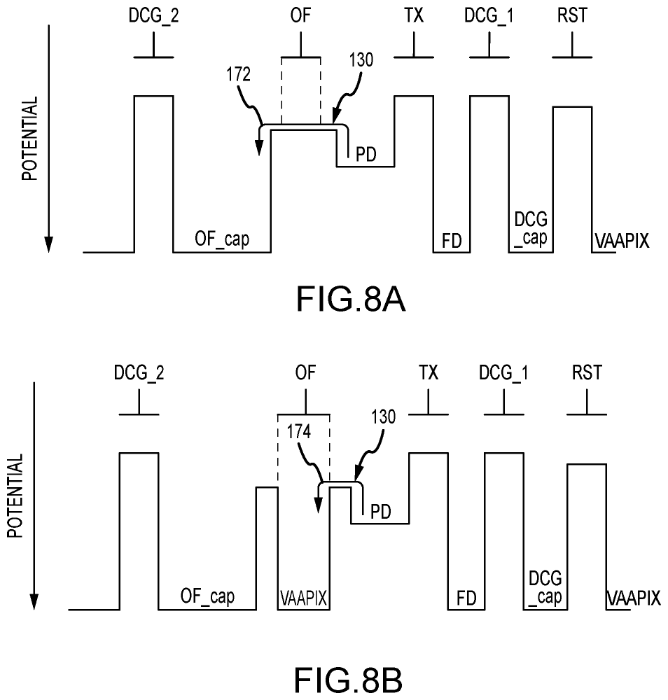

FIGS. 8A and 8B are potential diagrams showing various potentials within the pixel both when the overflow transistors are deasserted (as in FIG. 8A) and asserted (as in FIG. 8B). As shown, a potential barrier 130 may allow a certain amount of charge to accumulate in the photodiode. In FIG. 8A, when control signal OF is low and transistor 136 is deasserted, charge that overflows potential barrier 130 will be collected in overflow capacitor OF_Cap, as shown by arrow 172. In FIG. 8B, when control signal OF is high and transistor 136 is asserted, charge that overflows potential barrier 130 will be drained at voltage supply V_{AAPIX}, as shown by arrow 174.

The specific pixel components and layouts depicted herein are merely illustrative. It should be understood that modifications may be made to the pixel depending on the application for the particular pixel. For example, in some cases, DCG_cap 110 (and gain select transistor 108) may be omitted from the pixel. The DCG capacitor may be omitted in applications where multiple conversion gain modes are not required. Other modifications may be made to the pixel circuit if desired.

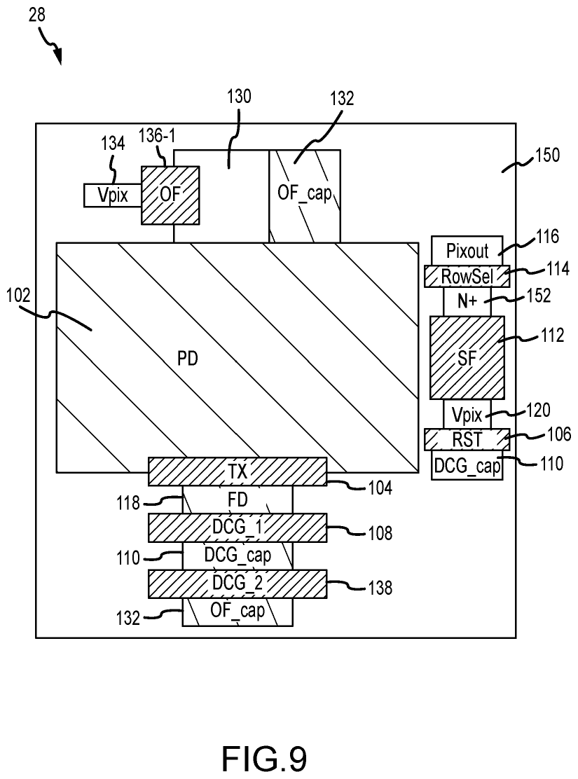

The layout of FIG. 5 is also merely illustrative. In FIG. 5, two overflow transistor gates 136-1 and 136-2 are depicted. Consequently, charge may be directed to voltage supply 134 on either side of potential barrier 130. However, this example is merely illustrative. In another possible layout, shown in FIG. 9, only one overflow transistor gate (136-1) is included. Overflow gate 136-1 is formed on a first side of potential barrier and overflow capacitor 132 is formed on a second, opposing side of potential barrier 130. The functionality of the pixel remains the same despite the modified layout. When control signal OF is low and transistor 136 is deasserted, charge that overflows potential barrier 130 is directed to overflow capacitor 132. When control signal OF is high and transistor 136 is asserted, charge that overflows potential barrier 130 is disposed of at voltage supply 134.

The potential barrier 130 with a corresponding overflow storage capacitor and transistor/voltage supply for disposing of charge may be incorporated at other desired positions within a pixel circuit if desired.

The foregoing is merely illustrative of the principles of this invention and various modifications can be made by those skilled in the art. The foregoing embodiments may be implemented individually or in any combination.

1. An imaging pixel comprising:
a photodiode configured to generate charge in response to incident light;
a floating diffusion region;
a transfer transistor coupled between the photodiode and the floating diffusion region;
a charge overflow structure that forms a potential barrier above which charge will overflow from the photodiode;
a bias voltage supply terminal;
a transistor that is interposed between the charge overflow structure and the bias voltage supply terminal;
a storage capacitor, wherein the overflow charge from the photodiode is disposed of at the bias voltage supply terminal when the transistor is asserted and wherein the overflow charge from the photodiode is stored at the storage capacitor when the transistor is deasserted; and
control circuitry configured to repeatedly assert and deassert the transistor throughout an integration time.

2. The imaging pixel defined in claim 1, wherein the charge overflow structure comprises a doped semiconductor portion.

3. The imaging pixel defined in claim 1, wherein the charge overflow structure is formed by a transistor that is biased at a predetermined level.

4. (canceled)

5. The imaging pixel defined in claim 1, wherein the transistor is asserted for a percentage of time during each integration time and wherein the control circuitry is configured to dynamically update the percentage of time.

6. The imaging pixel defined in claim 1, further comprising:
an additional capacitor; and
a gain select transistor interposed between the additional capacitor and the floating diffusion region.

7. The imaging pixel defined in claim 6, further comprising:
an additional transistor that is interposed between the storage capacitor and the gain select transistor.

8. The imaging pixel defined in claim 7, further comprising:
a reset transistor that is interposed between the gain select transistor and an additional bias voltage supply terminal; and
a source follower transistor having a gate coupled to the floating diffusion region.

9. The imaging pixel defined in claim 1, wherein the photodiode has first and second opposing sides, wherein the transfer transistor is formed on the first side of the photodiode, and wherein the charge overflow structure is formed on the second side of the photodiode.

10. An imaging pixel comprising:
a photodiode configured to generate charge in response to incident light;
a floating diffusion region;
a transfer transistor coupled between the photodiode and the floating diffusion region;
a charge overflow structure that forms a potential barrier above which charge will overflow from the photodiode;
a bias voltage supply terminal;
a transistor that is interposed between the charge overflow structure and the bias voltage supply terminal;
a storage capacitor, wherein the overflow charge from the photodiode is disposed of at the bias voltage supply terminal when the transistor is asserted and wherein the overflow charge from the photodiode is stored at the storage capacitor when the transistor is deasserted; and
a p-type pinning layer that overlaps the charge overflow structure and a portion of the photodiode.

11. The imaging pixel defined in claim 9, wherein the charge overflow structure has first and second opposing sides, the imaging pixel further comprising:
a first conductive gate for the transistor that is interposed between the first side of the charge overflow structure and the bias voltage supply terminal; and
a second conductive gate for the transistor that is interposed between the second side of the charge overflow structure and the bias voltage supply terminal.

12. The imaging pixel defined in claim 9, wherein the charge overflow structure has first and second opposing sides, the imaging pixel further comprising:
a first conductive gate for the transistor that is interposed between the first side of the charge overflow structure and the bias voltage supply terminal, wherein the storage capacitor is formed on the second side of the charge overflow structure.

13-17. (canceled)

18. An imaging pixel comprising:
a substrate;
a photodiode formed in the substrate, wherein the photodiode has first and second opposing sides;
a floating diffusion region formed on the first side of the photodiode;
a transfer transistor that is interposed between the photodiode and the floating diffusion region;
a charge overflow structure formed on the second side of the photodiode, wherein the charge overflow structure has first and second opposing sides;
a first conductive gate formed on the first side of the charge overflow structure; and
a second conductive gate formed on the second side of the charge overflow structure.

19. The imaging pixel defined in claim 18, wherein the charge overflow structure comprises an n-type doped portion of the substrate.

20. The imaging pixel defined in claim 19, further comprising:
a p-type pinning layer that overlaps the charge overflow structure and a portion of the photodiode.

21. The imaging pixel defined in claim 1, wherein the charge overflow structure has first and second opposing sides, the imaging pixel further comprising:
a first conductive gate for the transistor that is interposed between the first side of the charge overflow structure and the bias voltage supply terminal, wherein the storage capacitor is formed on the second side of the charge overflow structure.

22. The imaging pixel defined in claim 5, wherein the control circuitry is configured to dynamically update the percentage of time based on incident light levels.

23. The imaging pixel defined in claim 10, wherein the photodiode has first and second opposing sides, wherein the transfer transistor is formed on the first side of the photodiode, and wherein the charge overflow structure is formed on the second side of the photodiode.
